(19) United States
(12) Patent Application Publication
(10) Pub. No.: US 2015/0295396 A1
(43) Pub. Date: Oct. 15, 2015

(54) EXPLOSION-PROOF AND SURFACE MOUNTED CIRCUIT PROTECTION UNIT

(71) Applicant: CHIN-CHUNG YANG, TAICHUNG CITY (TW)

(72) Inventor: CHIN-CHUNG YANG, TAICHUNG CITY (TW)

(21) Appl. No.: 14/252,908

(22) Filed: Apr. 15, 2014

(51) Int. Cl. H02H 3/08; H05K 5/03; H05K 5/00; H05K 1/18

(52) U.S. Cl. CPC H02H 3/08; H05K 1/181; H05K 5/03; H05K 5/0004; H05K 2201/10181

(57) ABSTRACT

An explosion-proof and surface mounted circuit protection unit has a base module, a fuse, and a base cover. The base module has a base body and two conductive units. The base body has multiple first combination parts. The conductive units are respectively mounted on the base body at an interval. The fuse is mounted on the base module and electrically connected with the conductive units. The base cover is mounted on the base module and has a cover body, multiple second combination parts, and an interval between the cover body and the base body. The second combination parts protrude on the cover body and are respectively combined with the first combination parts tightly. The explosion-proof and surface mounted circuit protection unit can provide an explosion-proof effect.

### BACKGROUND OF THE INVENTION

1. Field of the Invention

The present invention relates to a surface mounted protection unit, and more particularly to an explosion-proof and surface mounted circuit protection unit.

2. Description of Related Art

A circuit protection unit is applied on a circuit board to protect the circuit board. When a passing current is excessive, a fuse of the circuit protection unit is heat-melted and fractured to form an open circuit to interrupt the current. A conventional circuit protection unit has a base, two conductive units, a fuse, and a cover. The conductive units are mounted on the base at an interval. The fuse is electrically connected between the conductive units. The cover is mounted on and seals the base to accommodate the fuse. In use, the circuit protection unit is electrically soldered on a circuit board by the conductive units by means of surface mount technology.

However, when the passing current is overloaded and the fuse is heated and melted, a temperature in the circuit protection unit is increased, and then a volume of air in the circuit protection unit is increased. A barometric pressure of the air is increased, and then a gas explosion may occur easily. When the gas explosion occurs, the cover may be detached from the base.

### SUMMARY OF THE INVENTION

The main objective of the present invention is to provide an explosion-proof and surface mounted circuit protection unit to resolve the above-mentioned problems.

The explosion-proof and surface mounted circuit protection unit has a base module, a fuse, and a base cover.

The base module has a base body and two conductive units. The base body is insulated, and has two combining segments and multiple first combination parts respectively formed on the combining segments. The conductive units are respectively mounted on the combining segments at an interval. Each conductive unit extends from a top side to a bottom side of the combining segment.

The fuse is mounted on the base module and electrically connected with the conductive units.

The base cover is mounted on the base module and has a cover body, multiple second combination parts, and an interval. The cover body covers the base module and encloses the fuse. The second combination parts protrude on the cover body and are respectively combined with the first combination parts tightly. The interval is formed between the cover body and the base body.

Other objectives, advantages and novel features of the present invention will become more apparent from the following detailed description when taken in conjunction with the accompanying drawings.

### BRIEF DESCRIPTION OF THE DRAWINGS

FIG. 1 is a perspective view of a preferred embodiment of an explosion-proof and surface mounted circuit protection unit in accordance with the present invention;

FIG. 2 is a perspective exploded view of the explosion-proof and surface mounted circuit protection unit in FIG. 1;

FIG. 3 is a cross sectional side view of the explosion-proof and surface mounted circuit protection unit in FIG. 1; and

FIG. 4 is an operational cross sectional side view of the explosion-proof and surface mounted circuit protection unit in FIG. 1.

### DETAILED DESCRIPTION OF PREFERRED EMBODIMENT

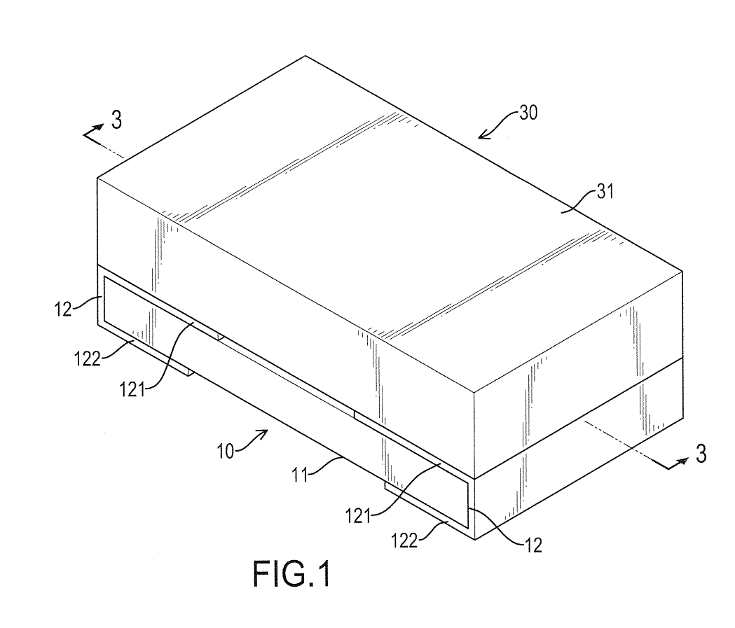

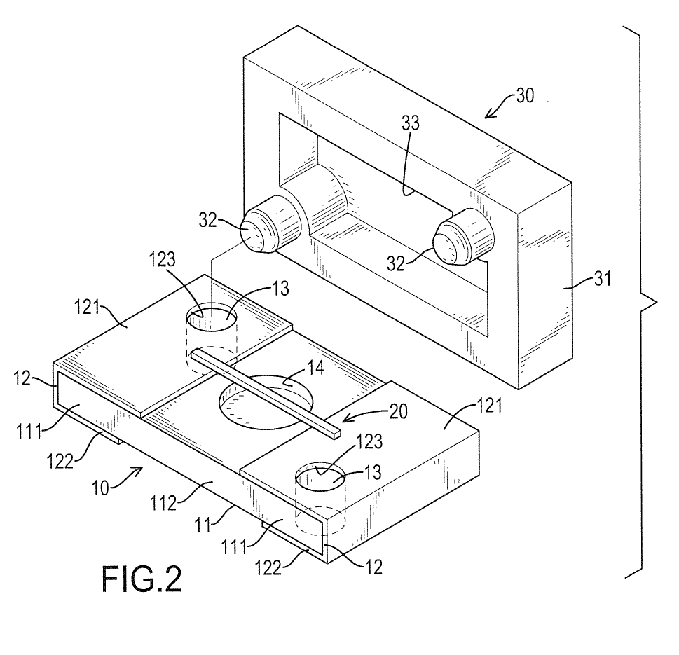

With reference to FIGS. 1 and 2, a preferred embodiment of an explosion-proof and surface mounted circuit protection unit in accordance with the present invention has a base module 10, a fuse 20 and a base cover 30.

With reference to FIGS. 1 to 3, the base module 10 has a base body 11 and two conductive units 12.

The base body 11 is made of an insulation material, such as ceramics, plastic and so on. The base body 11 has two combining segments 111, an interval segment 112, two first combination parts 13, and a base recess 14. The combining segments 111 are respectively defined as two ends of the base body 11. The interval segment 112 is connected between the combining segments 111. The first combination parts 13 are respectively recessed in the combining segments 111. The base recess 14 is recessed in a top side of the interval segment 112 of the base body 11.

The conductive units 12 are made of conductive material, are mounted on the base body 11 at an interval, and are mounted on the combining segments 111 respectively. Each conductive unit 12 is formed into a U shape and extends from a top side to a bottom side of the combining segment 111. Each conductive unit 12 has an abutting part 121, a soldering part 122, and a pad hole 123. The abutting part 121 is defined as a top side of the conductive unit 12, and is located on the top side of the combining segment 111. The soldering part 122 is defined as a bottom side of the conductive unit 12, and is located on the bottom side of the combining segment 111. The pad hole 123 is formed through the abutting part 121 and is aligned with the first combination part 13.

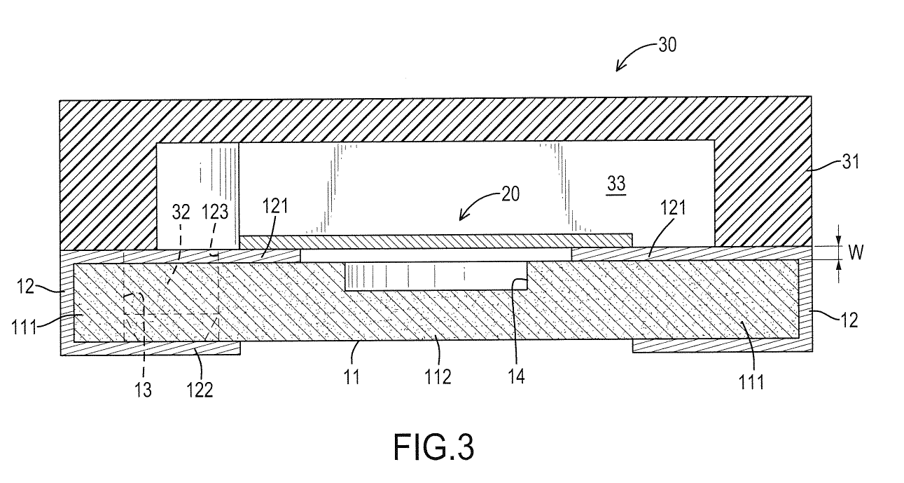

With reference to FIGS. 2 and 3, the fuse 20 is made of a conductive material, is mounted on a top side of the base module 10, and is mounted over the interval segment 112 and the base recess 14. The fuse 20 is electrically connected with the abutting parts 121 of the conductive units 12. When the fuse 20 is heat-melted and fractured into two individual segments, the base recess 14 provides a space for accommodating the individual segments.

With reference to FIGS. 1 to 3, the base cover 30 is made of an insulation material, such as ceramics, plastic and so on. The base cover 30 has a cover body 31, two second combination parts 32, and a cover recess 33. The cover body 31 covers the top side of the base module 10 and encloses the fuse 20. The second combination parts 32 protrude from a bottom side of the cover body 31 at an interval and are respectively inserted into the first combination parts 13 tightly via the pad holes 123, such that the base cover 30 can be fixed relative to the base module 10. When the base cover 30 is combined with the base module 10, an interval W is formed between the base cover 30 and the base module 10. The cover recess 33 is recessed in the bottom side of the cover body 31 and accommodates the fuse 20.

Alternatively, the first combination parts 13 may protrude from the top side of the base body 11, and the second combination parts 32 may be recessed in the bottom side of the cover body 31.

With reference to FIGS. 2 and 3, preferably, the base body 11 and the cover body 31 are cubes. The first combination parts 13 are respectively formed on two diagonal positions on the base body 11. The second combination parts 32 are respectively formed on two diagonal positions on the cover body 31 and respectively correspond in position to the first combination parts 13.

With reference to FIGS. 1 and 3, in use, the explosion-proof and surface mounted circuit protection unit is electrically combined on a circuit board by means of surface mount technology. Wherein, the soldering parts 122 are electrically combined with the circuit board. When an electric current passing through the fuse 20 is excessive, the fuse 20 is heat-melted and fractured into two individual segments to form an open circuit. Therefore, the circuit board can be protected from damage.

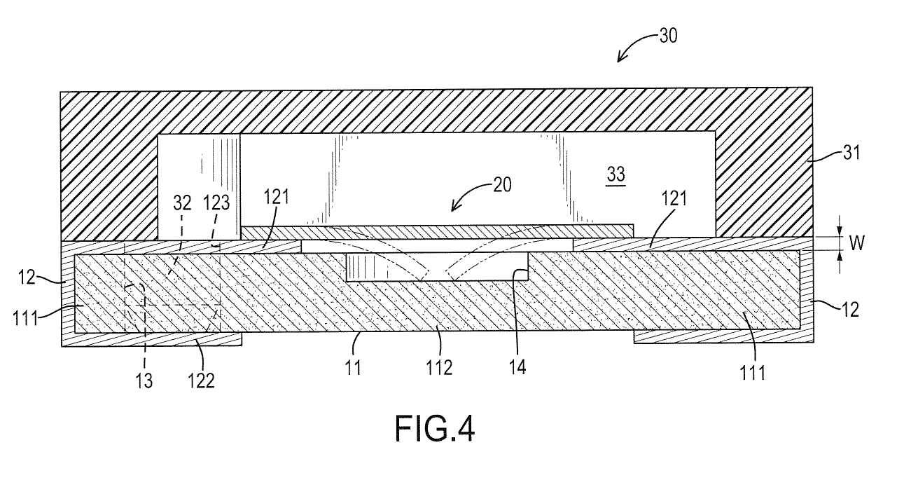

When the fuse 20 is heat-melted and fractured, a volume of air in the explosion-proof and surface mounted circuit protection unit is expanded due to high temperature. Therefore, a barometric pressure in the explosion-proof and surface mounted circuit protection unit is increased. The expanded air is discharged via the interval W between the base module 10 and the base cover 30 to prevent a gas explosion. When the expanded air is discharged via the interval W, the base cover 30 is combined with the base module 10 firmly since the first combination parts 13 and the second combination parts 32 are combined with each other tightly. Therefore, the base cover 30 can be kept from detaching from the base body 10. Furthermore, with reference to FIG. 4, the base recess 14 can accommodate the fractured fuse 20 to keep the fractured fuse 20 from electrical contact again.

From the above description, it is noted that the present invention has the following advantages. The expanded air can be discharged via the interval W to prevent gas explosion. The tightly combined first combination parts 13 and the second combination parts 32 can keep the base cove 30 from detaching from the base body 10. Therefore, the explosion-proof and surface mounted circuit protection unit can provide a protecting effect for the circuit board. The base recess 14 can keep the fractured fuse 20 from electrical contact again to further protect the circuit board.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An explosion-proof and surface mounted circuit protection unit having:
a base module having
a base body being insulated, and having
two combining segments; and
multiple first combination parts respectively formed on the combining segments; and
two conductive units respectively mounted on the combining segments at an interval, wherein each conductive unit extends from a top side to a bottom side of the combining segment;
a fuse mounted on the base module and electrically connected with the conductive units; and
a base cover mounted on the base module and having
a cover body covering the base module and enclosing the fuse;
multiple second combination parts protruding from the cover body and respectively combined with the first combination parts tightly; and
an interval formed between the cover body and the base body.

2. The explosion-proof and surface mounted circuit protection unit as claimed in claim 1, wherein the base body further has
an interval segment connected between the combining segments; and
a base recess recessed in the interval segment, wherein the fuse is crossed over the interval segment and the base recess.

3. The explosion-proof and surface mounted circuit protection unit as claimed in claim 2, wherein the base cover further has a cover recess recessed in the cover body and accommodating the fuse.

4. The explosion-proof and surface mounted circuit protection unit as claimed in claim 1, wherein
the base body has two first combination parts respectively recessed in the combining segments; and
the base cover has two second combination parts respectively protruding on the cover body, and respectively inserted into the first combination parts tightly.

5. The explosion-proof and surface mounted circuit protection unit as claimed in claim 2, wherein
the base body has two first combination parts respectively recessed in the combining segments; and
the base cover has two second combination parts respectively protruding on the cover body, and respectively inserted into the first combination parts tightly.

6. The explosion-proof and surface mounted circuit protection unit as claimed in claim 3, wherein
the base body has two first combination parts respectively recessed in the combining segments; and
the base cover has two second combination parts respectively protruding on the cover body, and respectively inserted into the first combination parts tightly.

7. The explosion-proof and surface mounted circuit protection unit as claimed in claim 4, wherein the base body and the cover body are cubes;
wherein the first combination parts are respectively formed on two diagonal positions on the base body, and the second combination parts are respectively formed on two diagonal positions on the cover body; and
wherein the second combination parts respectively correspond in position to the first combination parts.

8. The explosion-proof and surface mounted circuit protection unit as claimed in claim 5, wherein the base body and the cover body are cubes;
wherein the first combination parts are respectively formed on two diagonal positions on the base body, and the second combination parts are respectively formed on two diagonal positions on the cover body; and
wherein the second combination parts respectively correspond in position to the first combination parts.

9. The explosion-proof and surface mounted circuit protection unit as claimed in claim 6, wherein the base body and the cover body are cubes;
wherein the first combination parts are respectively formed on two diagonal positions on the base body, and the second combination parts are respectively formed on two diagonal positions on the cover body; and
wherein the second combination parts respectively correspond in position to the first combination parts.

10. The explosion-proof and surface mounted circuit protection unit as claimed in claim 4, wherein each conductive unit has
an abutting part defined as a segment located on the top side of the combining segment;
a soldering part defined as a segment located on the bottom side of the combining segment; wherein the fuse is electrically connected with the abutting parts of the conductive units.

11. The explosion-proof and surface mounted circuit protection unit as claimed in claim 5, wherein each conductive unit has
an abutting part defined as a segment located on the top side of the combining segment;
a soldering part defined as a segment located on the bottom side of the combining segment; wherein the fuse is electrically connected with the abutting parts of the conductive units.

12. The explosion-proof and surface mounted circuit protection unit as claimed in claim 6, wherein each conductive unit has
an abutting part defined as a segment located on the top side of the combining segment;
a soldering part defined as a segment located on the bottom side of the combining segment; wherein the fuse is electrically connected with the abutting parts of the conductive units.

13. The explosion-proof and surface mounted circuit protection unit as claimed in claim 7, wherein each conductive unit has
an abutting part defined as a segment located on the top side of the combining segment;
a soldering part defined as a segment located on the bottom side of the combining segment; wherein the fuse is electrically connected with the abutting parts of the conductive units.

14. The explosion-proof and surface mounted circuit protection unit as claimed in claim 8, wherein each conductive unit has
an abutting part defined as a segment located on the top side of the combining segment;
a soldering part defined as a segment located on the bottom side of the combining segment; wherein the fuse is electrically connected with the abutting parts of the conductive units.

15. The explosion-proof and surface mounted circuit protection unit as claimed in claim 9, wherein each conductive unit has
an abutting part defined as a segment located on the top side of the combining segment;
a soldering part defined as a segment located on the bottom side of the combining segment; wherein the fuse is electrically connected with the abutting parts of the conductive units.
